(19) United States
(12) Patent Application Publication
(10) Pub. No.: US 2015/0180042 A1
(43) Pub. Date: Jun. 25, 2015

(54) METHOD

(71) Applicants: Jas Pal Singh Badyal, Durham (GB); Thomas J. Wood, Durham (GB)

(72) Inventors: Jas Pal Singh Badyal, Durham (GB); Thomas J. Wood, Durham (GB)

(73) Assignee: SURFACE INNOVATIONS LIMITED, Oxfordshire (GB)

(21) Appl. No.: 14/344,380

(22) PCT Filed: Sep. 14, 2012
(86) PCT No.: PCT/GB2012/052277

§ 371 Date: Mar. 10, 2015

(30) Foreign Application Priority Data
Sep. 16, 2011 (GB) 1116025.6

(51) Int. Cl. H01M 4/88; C23C 16/18; H01B 1/02; C23C 16/515

(52) U.S. Cl. CPC H01M 4/886; C23C 16/515; C23C 16/18; H01B 1/02

(57) ABSTRACT

A method for forming a conducting nanocomposite layer on a substrate, the method comprising depositing a precursor on the substrate by plasma deposition, wherein the precursor comprises (i) a metal or metalloid centre, and (ii) one or more organic ligands, and wherein the conditions of the plasma deposition are tailored such that an organic matrix is retained in the resulting conducting nanocomposite layer.

### FIELD OF THE INVENTION

The present invention relates to methods for forming a conducting nanocomposite layer on a substrate, to conducting nanocomposite layers produced using such methods, to an electrode comprising such a conducting nanocomposite layer and to an apparatus comprising such a conducting nanocomposite layer.

### BACKGROUND TO THE INVENTION

Conducting nanocomposite layers are used in a wide variety of applications such as, for example, in fuel cells, batteries, sensors, integrated circuits, catalysis, photonics, proton exchange membranes, vapour sensors, data storage, biosensing, cell imaging, and thermoresponsive materials.

In fuel cells, for example, a conducting nanocomposite layer may form part of an electrochemical system. Fuel cells are electrochemical conversion devices, which are supplied continuously by a fuel (normally hydrogen or methanol) and an oxidant (normally air or oxygen). A polymer electrolyte membrane fuel cell (PEMFC) consists of a membrane electrode assembly (MEA), which is supplied with fuel and oxidant. Hydrogen gas (or sometimes methanol in the case of a direct methanol fuel cell) is catalytically oxidised at the anode 1 according to the following half-reaction:

H₂→2H⁺+2e⁻.

Oxygen is catalytically reduced at the cathode 2 according to the half-reaction:

½O₂+2H⁺+2e⁻→H₂O.

This gives the overall reaction:

H₂+½O₂→H₂O (E°=1.229 V).

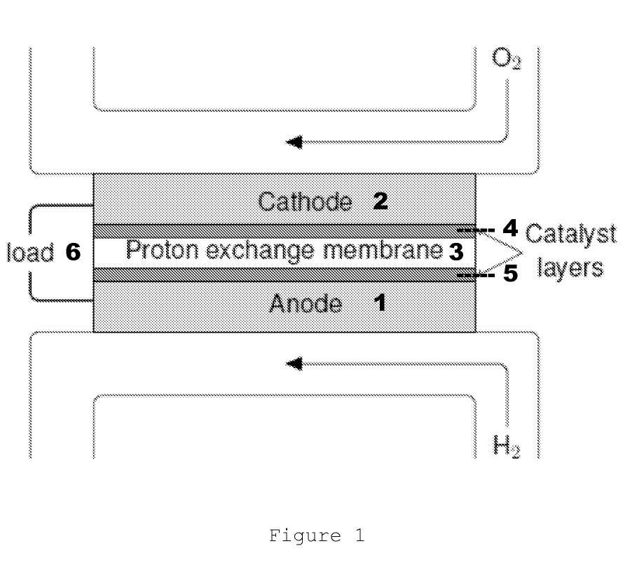

As a result of this chemical reaction a circuit is completed with the protons as the charge carriers across the proton exchange membrane 3. As an example, a basic schematic of a PEMFC is shown in FIG. 1, which includes an anode 1 comprising an anode catalyst layer 5, a cathode 2 comprising a cathode catalyst layer 4, a proton exchange membrane 3 and a load 6.

The oxidation of H₂ gas at the anode producing protons is much faster than the corresponding oxygen reduction reaction (ORR), as shown by the overpotentials at the cathode. An additional disadvantage with slow oxygen reduction is that the partial reduction reaction, O₂+2H⁺+2e⁻→H₂O₂, produces the stable intermediate hydrogen peroxide which attacks the proton exchange membrane with resulting loss of efficiency. A certain minimum catalyst loading is required in order to avoid the longevity of the peroxide intermediate. Ideally, the cathode catalyst should therefore have the following properties: (1) able to effectively catalyse reduction of oxygen under acidic conditions (2) able to conduct electrons (otherwise there is no circuit formed), (3) porous to oxygen gas, (4) able to conduct protons (which are required for the reaction), (5) stable in acid conditions, (6) long lived (not easily poisoned), (7) low cost. Currently, commercial preference lies with platinum supported on a carbon matrix printed with an ionomer as the cathode catalyst.

The current locus of the main bulk of research regarding PEMFCs is on reducing the platinum content of PEMFCs, and the associated cost, without reducing their performance or longevity; three main approaches have been taken to achieve this. One approach has been to look for non-platinum containing catalysts (either metal or non-metal). Non-precious metal alternatives to platinum or transition metals are generally based on replicating porphyrin-metal complexes, either using nitrogen-functionalized carbon structures with or without a metal centre, or intrinsically conducting polymers. Another approach has been to increase the platinum surface area by synthesizing nanostructures, meaning that less platinum is required to achieve the same surface area of platinum available for catalysis. A further approach has been to alloy platinum with another transition metal to form a core-shell structure. The use of platinum-only nanostructures in PEMFCs is very expensive, even with high surface area substrates, so binary and ternary core-shell platinum alloy nanostructures are being heavily investigated as a cheaper alternative. These core-shell structures are nanosized particles with a transition metal core with a platinum shell coating. This reduces the amount of platinum needed, whilst ensuring the surface area of platinum available for catalysis remains constant. Transition metals that have been used with platinum include copper, cobalt, gold, iron, nickel, palladium, ruthenium, tin, iridium, lead, and molybdenum. Core-shell nanoparticles can also lead to greater catalytic activity. Core-shell structures based on copper have proved popular due to enhanced catalytic activity within fuel cells and the ready availability of copper.

Platinum nanostructures have been synthesized by a variety of methods including photoreduction, hydrothermal (aqueous) or solvothermal (nonaqueous) processes, sol-gel synthesis, rf sputtering, pulsed laser ablation, ion or electron beam deposition, and electrochemical techniques.

Copper nanostructures have also been put down by various methods, with special attention paid to copper thin films for electronic applications. Of these methods, using an organometallic copper precursor in order to produce a copper thin film by physical or chemical vapour deposition is particularly suited to conformal coating of rough substrates. In these methods, the deposition conditions are sufficiently harsh that the ligands are removed and/or destroyed, resulting in an elemental copper film.

Plasma enhanced chemical vapour deposition (PECVD) of precursors has been used to manufacture various parts of fuel cells, including membrane electrode assemblies, catalyst layers, silica-based membranes, proton exchange membranes, and for modification of commercially available membranes.

It has not, however, previously been used to manufacture a conducting nanocomposite layer, which comprises electrical conducting or semiconducting moieties in a conducting matrix.

In existing methods, conducting nanocomposite layers have been formed by applying a paste containing a relevant metal, such as platinum or palladium, onto a pre-existing layer which has conducting properties.

Organometallic precursors have previously been used to manufacture elemental metal films, such as metal thin films for electronic applications. Organometallic precursors have one or more metal or metalloid centres with one or more organic ligands surrounding it. During the known process of manufacturing elemental metal films, the deposition conditions are sufficiently harsh that the organic ligands are separated and removed from the metal or metalloid centres and/or destroyed, resulting in only an elemental metal film being deposited on a substrate.

The most common approaches for producing nanocomposite materials and films involve sol-gel synthesis, in-situ photocuring, layer-by-layer deposition, self-assembly, surface initiated polymerization, and electrochemical deposition. These tend to be wet-chemical methods and suffer from a number of drawbacks such as the requirement for multiple steps, or potential damage to substrates arising from high processing temperatures.

Dry (solventless) approaches, such as plasma enhanced chemical vapour deposition combined with rf sputtering from an inorganic target to produce catalytic, metal-containing nanocomposite films are also known. However, the high input power levels required to induce sputtering can cause damage to temperature-sensitive substrates. Similarly, the high temperatures necessary for chemical vapour deposition techniques also make them unsuitable. This approach can be cumbersome, inefficient, and sometimes irreproducible.

It is an aim of the present invention to provide a method for forming a conducting nanocomposite layer on a substrate, embodiments of which can enhance the ease and/or efficiency with which such conducting nanocomposite layers can be produced, and can also enhance their performance characteristics.

### SUMMARY OF THE INVENTION

According to a first aspect of the present invention there is provided a method for forming a conducting nanocomposite layer on a substrate, the method comprising depositing a precursor on the substrate by plasma deposition, wherein the precursor comprises
(i) a metal or metalloid centre, and
(ii) one or more organic ligands,
   and wherein the conditions of the plasma deposition are tailored such that an organic matrix is retained in the resulting conducting nanocomposite layer.

In this context, the term “conducting” means that the nanocomposite layer is able to conduct ions (including, for example, protons), or electrons, or has semiconducting properties, or that the nanocomposite layer has any combination of these properties. The term “conducting” therefore embraces, for example, ion-conducting; electron-conducting; semiconducting; ion-conducting and electron-conducting; ion-conducting and semiconducting; electron-conducting and semiconducting; and ion-conducting and electron-conducting and semiconducting.

The term “organic” in this context means comprising carbon atoms.

In the method of the invention, the ligands are not separated and removed from the metal or metalloid centres and/or destroyed during deposition, which makes it possible to deposit a complete conducting nanocomposite layer, containing both metal (or metalloid) moieties and an organic matrix derived from the one or more organic ligands, in a single step. In the method of the invention, rather than removing the ligands from the precursor during deposition, the conditions of the plasma enhanced chemical vapour deposition are tailored such that an organic matrix is retained in the resulting conducting nanocomposite layer. This organic matrix can provide ion-conductivity, electron-conductivity, semiconductivity, or any combination thereof, in the resulting deposited conducting nanocomposite layer. The retention of the organic matrix can be achieved by using mild deposition conditions (such as, for example, low temperature and/or low power).

EP 2322530 describes the deposition of a family of Group 4 metal precursors using chemical vapour deposition (CVD) or atomic layer deposition (ALD) processes. This document is concerned with producing inorganic films such as metal oxides, metal nitrides and metal silicates. The depositions described in this document are performed under conditions which are tailored to remove any organic part of the precursor.

As stated above, in the method of the invention, the conditions of the plasma enhanced chemical vapour deposition are tailored such that an organic matrix, derived from the one or more organic ligands, is retained in the resulting conducting nanocomposite layer. The method of the invention can modify the organic ligand to produce useful functionalities from the ligand. The plasma can, for example, modify the organic ligand such that there are multiple carbonyl-containing moieties within the film (see the examples). These carbonyl containing moieties can include carboxylic acid groups, which can provide ion(proton)-conduction.

The conducting nanocomposite layer resulting from the method of the invention can take the form of metal or metalloid moieties in an organic ligand matrix.

In embodiments of the invention, a nanocomposite will be a bulk matrix within which nanostructures of a material are located, which nanostructures differ either in chemical or physical structure from the surrounding matrix.

In the method of the invention, the precursor is deposited on the substrate by plasma deposition, such as, for example, plasma enhanced chemical vapour deposition (PECVD). Plasma deposition allows the formation of conformal coatings of rough substrates. Furthermore, plasma deposition allows for the formation of covalent bonds between the substrate and the deposited layer regardless of the chemical nature of the substrate used. This method is therefore substrate-independent, unlike many other deposition methods such as e.g. electrodeposition, solution-contacting, atomic layer deposition (ALD), and thermal chemical vapour deposition. In addition to this, in plasma deposition there is no requirement for high temperatures, it does not require the presence of a solvent, it requires only a one-step procedure, and it can be used with a wide range of precursors.

In an embodiment, the plasma deposition is performed at a temperature of up to 300° C., up to 250° C., up to 200° C., up to 150° C., or up to 100° C.

In an embodiment, the plasma deposition is performed at a temperature of up to 200° C., up to 195° C., up to 190° C., up to 185° C., up to 180° C., up to 175° C., up to 170° C., up to 165° C., up to 160° C., up to 155° C., up to 150° C., up to 145° C., up to 140° C., up to 135° C., up to 130° C., up to 125° C., up to 120° C., up to 115° C., up to 110° C., up to 105° C., or up to 100° C.

In an embodiment, the plasma deposition is performed at a temperature of up to 100° C., up to 95° C., up to 90° C., up to 85° C., up to 80° C., up to 75° C., up to 70° C., up to 65° C., up to 60° C., up to 55° C., up to 50° C., up to 45° C., up to 40° C., up to 35° C., up to 30° C., or up to 25° C.

Such mild temperatures can allow a wide variety of substrates to be used, including, for example, porous membranes. Low temperatures can also provide increased safety and the equipment used does not need to be as robust as required for high temperature applications.

In an embodiment, the plasma deposition is performed at a temperature of from 0° C., from 5° C., from 10° C., from 15° C., from 20° C., from 30° C., from 25° C., from 35° C., from 40° C., from 45° C., from 50° C., from 55° C., from 60° C., from 65° C., or from 70° C.

In an embodiment, the plasma deposition is performed at a temperature of from 0 to 200° C., from 0 to 150° C., from 0 to 100° C., from 50 to 200° C., from 50 to 150° C., or from 50 to 100° C.

In an embodiment, the plasma deposition occurs at a power density of 0.001 mW/cm³ to 500 W/cm³.

In an embodiment, the plasma deposition occurs at a power density of 0.001 mW/cm³ to 100 mW/cm³, 0.001 mW/cm³ to 50 mW/cm³, 1 mW/cm³ to 500 W/cm³, 1 mW/cm³ to 100 mW/cm³, or 1 mW/cm³ to 50 mW/cm³.

In an embodiment, the plasma deposition occurs at a power density of about 4 mW/cm³. In an embodiment, the plasma deposition occurs at a power density of about 10 mW/cm³. In an embodiment, the plasma deposition occurs at a power density of about 21 mW/cm³.

In an embodiment, the plasma deposition is a continuous wave plasma deposition process. A continuous wave plasma deposition process can allow for quicker deposition, and the deposited layers can be less soluble, i.e. potentially more durable.

In an embodiment, the plasma deposition is a pulsed plasma deposition process. A pulsed plasma deposition process can allow for more functional retention in the deposited layer, which can lead to better performance.

In an embodiment, the conducting nanocomposite layer is ion-conducting (in particular, proton-conducting) and/or electron-conducting.

The metal or metalloid centre may contribute electron-conductivity or semiconductivity in the resulting deposited conducting nanocomposite layer.

In an embodiment, the metal or metalloid centre gives rise to electron-conducting or semiconducting species in the resulting conducting nanocomposite layer.

The organic ligands may contribute ion-conductivity, proton-conductivity, electron-conductivity or semiconductivity, or any combination thereof, in the resulting deposited conducting nanocomposite layer.

In an embodiment, the one or more organic ligands give rise to ion-conductivity in the resulting conducting nanocomposite layer. In an embodiment, the one or more organic ligands give rise to proton-conductivity in the resulting conducting nanocomposite layer.

In an embodiment, the one or more organic ligands give rise to electron-conductivity in the resulting conducting nanocomposite layer.

In an embodiment, the one or more organic ligands give rise to semiconductivity in the resulting conducting nanocomposite layer.

In an embodiment, the combination of the metal or metalloid centre with the one or more organic ligands gives rise to conductivity in the resulting conducting nanocomposite layer.

In this context, the term “conductivity” embraces, for example, ion-conductivity; electron-conductivity; semiconductivity; ion-conductivity and electron-conductivity; ion-conductivity and semiconductivity; electron-conductivity and semiconductivity; and ion-conductivity and electron-conductivity and semiconductivity.

The specific conducting properties of the nanocomposite layer can therefore be tailored by choosing the appropriate precursor.

For example, zinc acetylacetonate, titanium isopropoxide and tin acetate are examples of suitable precursors for the formation of a conducting nanocomposite layer containing electron-conducting or semiconducting species (resulting from the metal centres) which are embedded within an ion- (and more specifically proton-) conducting matrix (resulting from the organic ligands).

Suitable precursors have one or more metal or metalloid centres with one or more organic ligands surrounding it.

Suitable metals or metalloids can include transition metals (including, but not limited to Sc, Ti, V, Cr, Mn, Fe, Co, Ni, Cu, Y, Zr, Nb, Mo, Tc, Ru, Rh, Pd, Ag, Hf, Ta, W, Re, Os, Ir, Pt, and Au), post transition metals (including, but not limited to Al, Zn, Ga, Cd, In, Sn, Hg, Tl, Pb, and Bi), metalloids (including, but not limited to B, Si, Ge, As, Sb, and Te), alkali metals (including, but not limited to Li), alkaline earth metals (including, but not limited to Mg, Ca, Sr, and Ba), lanthanoids (including, but not limited to La, Ce, Pr, Nd, Sm, Eu, Gd, Tb, Dy, Ho, Er, Tm, Yb, and Lu), and actinoids (including, but not limited to Ac, Th, Pa, U, Np, and Pu), or any combination thereof.

In an embodiment, the precursor comprises (i) a metal centre, and (ii) one or more organic ligands.

In an embodiment, the metal or metalloid centre comprises platinum, palladium, ruthenium, rhodium, gold, silver, copper, nickel, iron, cobalt, molybdenum, titanium, zinc, tin, or any combination thereof.

In an embodiment, the metal or metalloid centre comprises platinum or copper.

In an embodiment, the metal or metalloid centre comprises platinum. The method of the invention can reduce the required platinum content and hence the associated cost in applications which routinely use platinum. It can do this by increasing particle size dispersion, i.e. for a fixed amount of platinum, smaller particles give rise to a larger surface area. It can also do this by forming alloy particle structures, either by co-feeding in the respective metal precursors together, for example by co-feeding platinum and copper precursors, or by using a metal precursor which contains both platinum and the alloying metal within the same molecule.

In an embodiment, the metal or metalloid centre comprises copper.

Suitable organic ligands are those which, when deposited via plasma deposition, can result in an organic matrix. The ligands may, for example, be organic ligands composed of one or more non-metal atoms where the atom closest to the metal or metalloid centre can include boron, carbon (including, but not limited to carbonyl, cyano, cyclopentadienyl, cyclooctodiene, alkyls, and alkenes), nitrogen (including, but not limited to amido, imido, thiocyanates, and nitrogen-containing heterocycles), oxygen (including, but not limited to alkoxides, alkanoates, optionally substituted acetonates such as acetylacetonate or hexafluoroacetylacetonate, and diketones), silicon (including, but not limited to fluorine-containing silicon ligands), phosphorus, sulphur (including, but not limited to thiolates, and thiocyanates), or any combination thereof.

In an embodiment, the one or more organic ligands comprise ligands which, when deposited via plasma deposition, can form acid groups.

In an embodiment, the one or more organic ligands comprise carbonyl-containing ligands.

In an embodiment, the one or more organic ligands comprise ligands selected from at least partially substituted or unsubstituted acetylacetonate ligands, isopropoxide ligands, acetate ligands, and any combination thereof.

In an embodiment, the one or more ligands comprise at least partially substituted or unsubstituted acetylacetonate ligands. As discussed above, the method of the invention can modify the organic ligand to produce useful functionalities from the ligand, such as, for example, acid groups from diketonate groups.

In an embodiment, the one or more organic ligands comprise hexafluoroacetylacetonate. The trifluoromethyl groups in hexafluoroacetylacetonate can give the precursor a higher vapour pressure, thus enabling lower temperature deposition. Furthermore, if the precursor is modified within the plasma to form carboxylic acid groups (also see the examples), the effect of the acid contribution to ion-conductivity is enhanced by the trifluoromethyl groups which render stronger acid groups (therefore more dissociation, therefore higher ion conductivity) in the final film.

Suitable precursors include aluminium hexafluoroacetylacetonate, barium hexafluoroacetylacetonate, bismuth(III) hexafluoroacetylacetonate, calcium hexafluoroacetylacetonate, chromium(III) hexafluoroacetylacetonate, cobalt(II) hexafluoroacetylacetonate, copper(I) hexafluoroacetylacetonate, erbium(III) hexafluoroacetylacetonate, gold hexafluoroacetylacetonate, indium(III) hexafluoroacetylacetonate, lead(II) hexafluoroacetylacetonate, magnesium hexafluoroacetylacetonate, manganese(II) hexafluoroacetylacetonate, neodymium(III) hexafluoroacetylacetonate, nickel(II) hexafluoroacetylacetonate, palladium(II) hexafluoroacetylacetonate, platinum(II) hexafluoroacetylacetonate, praseodymium(III) hexafluoroacetylacetonate, rhodium(I) hexafluoroacetylacetonate, ruthenium(III) hexafluoroacetylacetonate, scandium(III) hexafluoroacetylacetonate, silver(I) hexafluoroacetylacetonate, sodium hexafluoroacetylacetonate, strontium hexafluoroacetylacetonate, thallium(I) hexafluoroacetylacetonate, thorium hexafluoroacetylacetonate, tin(II) hexafluoroacetylacetonate, ytterbium(III) hexafluoroacetylacetonate, yttrium(III) hexafluoroacetylacetonate, zinc hexafluoroacetylacetonate, zirconium(IV) hexafluoroacetylacetonate and copper(II) hexafluoroacetylacetonate. All the aforementioned precursors may be hydrates or anhydrous, and/or have extra non-acetylacetonato ligands.

Suitable precursors also include zinc acetylacetonate, titanium isopropoxide, and tin acetate. These precursors may be hydrates or anhydrous.

In an embodiment, the precursor comprises a compound selected from platinum(II) hexafluoroacetylacetonate, copper(II) hexafluoroacetylacetonate, zinc acetylacetonate, titanium isopropoxide, tin acetate, and any combination thereof.

In an embodiment, the precursor comprises platinum(II) hexafluoroacetylacetonate or copper(II) hexafluoroacetylacetonate.

In an embodiment, the precursor comprises platinum(II) hexafluoroacetylacetonate.

In an embodiment, the precursor comprises copper(II) hexafluoroacetylacetonate. Copper(II) hexafluoroacetylacetonate has a good vapour pressure (sublimes at 120° C. at 0.1 mbar). It has been used previously to deposit elemental copper films, copper oxides, and copper alloys by both CVD and PECVD for potential microelectronics applications. In these methods, the deposition conditions are sufficiently harsh that the ligands are removed and/or destroyed, resulting in an elemental copper film.

The substrate on which the precursor is deposited can be any substrate. In an embodiment, the substrate comprises a polymer, such as, for example, polytetrafluoroethylene (PTFE).

In the method of the invention, the step of depositing the precursor on the substrate may also comprise co-depositing one or more additional materials, such as, for example, additional precursors, which allows for further options for specific tailoring of the conducting properties of the nanocomposite layer.

For example, when two different precursors are co-fed, the metal (or metalloid) centre of one precursor could provide electron-conducting species and the metal (or metalloid) centre of the other one could provide semiconducting species, while the ligands from both precursors could provide ion- (and more specifically proton-) conduction, to give a net overall nanocomposite layer which exhibits electron-, ion- (and more specifically proton-), and semi-conducting behaviour.

In an embodiment, the method of the invention further comprises co-depositing one or more additional materials.

In an embodiment, the step of depositing the precursor on the substrate further comprises co-depositing one or more additional materials.

In this context “co-depositing” means simultaneously or sequentially. In an embodiment, it means simultaneously. In another embodiment, it means sequentially.

The one or more additional materials which are co-deposited do not necessarily need to be volatile, because they can, for example, be sprayed. All precursors can be mixed with other precursors, gases, or physical deposited species (such as from sputtering).

The one or more additional materials which are co-deposited may, for example, be selected from additional precursors comprising a metal or metalloid centre and one or more ligands; electron-conducting carbon particles; semiconducting carbon particles; organometallic compounds; metal salts; colloidal particles (including, for example, metallic and semiconducting colloidal particles); functionalised colloidal particles; polymer particles (including, for example, acidic, conducting, and semiconducting polymer particles); inorganic particles (including, for example, metallic and semiconducting inorganic particles); sulphur compounds (including, for example, sulphur oxides such as sulphur dioxide, and organothiols such as ethane thiol); oxygen-containing carbon compounds (including, for example, acrylic acid and maleic anhydride); fluorocarbons (including, for example, tetrafluoroethylene and perfluoroacrylates); and any combination thereof.

In an embodiment, the one or more additional materials which are co-deposited are selected from additional precursors comprising a metal or metalloid centre and one or more organic ligands; electron-conducting carbon particles; semiconducting carbon particles; and any combination thereof.

In an embodiment, the method of the invention further comprises the step of a post-deposition treatment. This treatment can be performed, for example, in order to increase the percentage metal content, or to reduce the metal or metalloid, or to increase ion conductivity, or to increase electrical conductivity, or to increase durability.

In an embodiment, the method of the invention further comprises the step of a post-deposition hydrogen plasma treatment.

According to a second aspect of the present invention there is provided a conducting nanocomposite layer which is obtainable by a method according to the first aspect of the invention.

According to a third aspect of the present invention there is provided a conducting nanocomposite layer comprising metal or metalloid moieties embedded in a conducting organic ligand matrix.

In this context, the term “conducting” means that the nanocomposite layer or the matrix, as the case may be, is able to conduct ions, or electrons, or have semiconducting properties, or that the nanocomposite layer or the matrix has any combination of these properties. The term “conducting” therefore embraces, for example, ion-conducting; electron-conducting; semiconducting; ion-conducting and electron-conducting; ion-conducting and semiconducting; electron-conducting and semiconducting; and ion-conducting and electron-conducting and semiconducting.

In an embodiment, the conducting nanocomposite layer is present on a substrate.

In an embodiment, the conducting nanocomposite layer is ion-conducting and/or electron-conducting.

In an embodiment, the metal or metalloid moieties provide electron-conductivity or semiconductivity.

In an embodiment, the conducting matrix provides ion-conductivity, proton-conductivity, electron-conductivity or semiconductivity, or any combination thereof.

In an embodiment, the conducting matrix provides ion-conductivity.

In an embodiment, the conducting matrix provides proton-conductivity.

In an embodiment, the conducting matrix provides electron-conductivity.

In an embodiment, the conducting matrix provides semiconductivity.

In an embodiment, the conducting nanocomposite layer of the third aspect of the invention further comprises electron-conducting carbon moieties or semiconducting carbon moieties embedded in the conducting matrix.

In an embodiment, the conducting nanocomposite layer according to the second or third aspect of the invention has a thickness of 1 nm to 100 μm. In an embodiment, the conducting nanocomposite layer according to the second or third aspect of the invention has a thickness of 1 nm to 500 nm, or of 50 nm to 500 nm. In an embodiment, the conducting nanocomposite layer according to the second or third aspect of the invention has a thickness of 50 nm to 100 μm.

In an embodiment, the conducting nanocomposite layer according to the second or third aspect of the invention comprises metal or metalloid nanoparticles. In an embodiment, the metal or metalloid nanoparticles have a size in the range of 1 to 500 nm diameter, or 1 to 100 nm diameter, or 1 to 50 nm diameter, or 1 to 10 nm diameter, or 1 to 5 nm diameter.

According to a fourth aspect of the present invention there is provided an electrode comprising a substrate and a conducting nanocomposite layer according to the second or third aspect of the invention on said substrate.

In an embodiment, the electrode is a cathode. In another embodiment, the electrode is an anode. In an embodiment, the electrode is suitable and/or adapted for use in a fuel cell.

According to a fifth aspect of the invention there is provided an apparatus comprising a substrate and a conducting nanocomposite layer according to the second or third aspect of the invention on said substrate.

In an embodiment, the apparatus is a conducting apparatus, the operation of which involves conduction of ions (including, for example, protons), or electrons, or semiconduction, or any combination of these types of conduction. The term “conducting” therefore embraces, for example, ion-conducting; electron-conducting; semiconducting; ion-conducting and electron-conducting; ion-conducting and semiconducting; electron-conducting and semiconducting; and ion-conducting and electron-conducting and semiconducting.

In a specific embodiment, the conducting apparatus is a fuel cell. In a specific embodiment, the conducting apparatus is a battery. In a specific embodiment, the conducting apparatus is a sensor. In a specific embodiment, the conducting apparatus is an integrated circuit, such as, for example, a computer chip. In a specific embodiment, the conducting apparatus is a proton exchange membrane. In a specific embodiment, the conducting apparatus is a vapour sensor.

Throughout the description and claims of this specification, the words “comprise” and “contain” and variations of the words, for example “comprising” and “comprises”, mean “including but not limited to”, and do not exclude other moieties, additives, components, integers or steps. Moreover the singular encompasses the plural unless the context otherwise requires: in particular, where the indefinite article is used, the specification is to be understood as contemplating plurality as well as singularity, unless the context requires otherwise.

Preferred features of each aspect of the invention may be as described in connection with any of the other aspects. Other features of the invention will become apparent from the following examples. Generally speaking the invention extends to any novel one, or any novel combination, of the features disclosed in this specification (including any accompanying claims and drawings). Thus features, integers, characteristics, compounds, chemical moieties or groups described in conjunction with a particular aspect, embodiment or example of the invention are to be understood to be applicable to any other aspect, embodiment or example described herein unless incompatible therewith. Moreover unless stated otherwise, any feature disclosed herein may be replaced by an alternative feature serving the same or a similar purpose.

Where upper and lower limits are quoted for a property, for example for the concentration of a component or a temperature, then a range of values defined by a combination of any of the upper limits with any of the lower limits may also be implied.

In this specification, references to properties such as solubilities, liquid phases and the like are—unless stated otherwise—to properties measured under ambient conditions, ie at atmospheric pressure and at a temperature of from 18 to 25° C., for example about 20° C.

### DETAILED DESCRIPTION

The present invention will now be further described with reference to the following non-limiting examples and the accompanying figures, of which:

FIG. 1 shows a basic schematic of a polymer electrolyte membrane fuel cell (PEMFC).

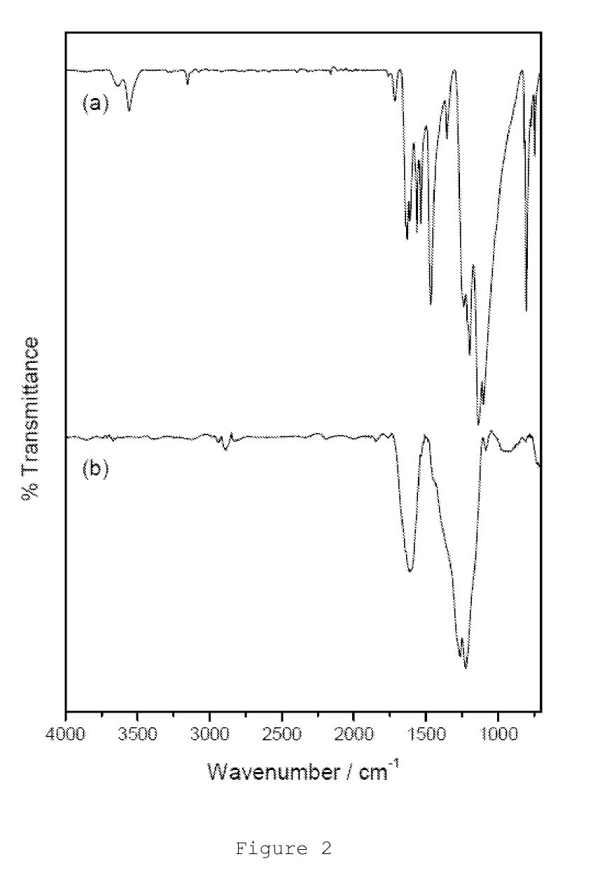

FIG. 2 shows Fourier transform infrared (FTIR) spectra of (a) copper(II) hexafluoroacetylacetonate hydrate precursor, and (b) plasma deposited copper(II) hexafluoroacetylacetonate.

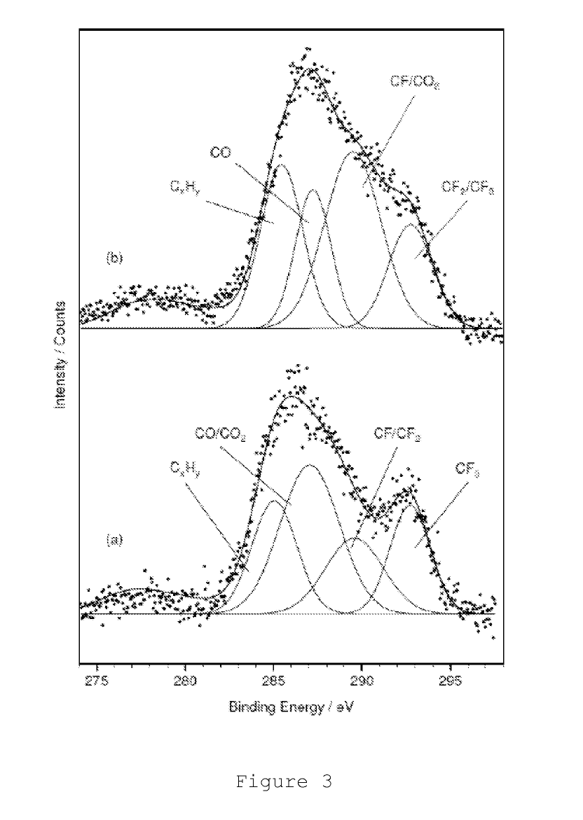

FIG. 3 shows C(1s) X-ray photoelectron spectroscopy (XPS) spectra of copper(II) hexafluoroacetylacetonate deposited with (a) 2 W plasma power and (b) 5 W plasma power. Satellite peaks (not shown individually) were also used in fitting the spectra.

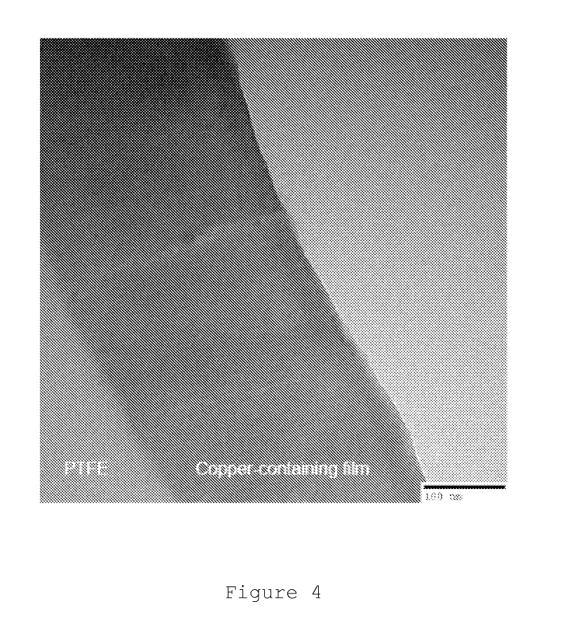

FIG. 4 shows a transmission electron microscopy (TEM) image of copper(II) hexafluoroacetylacetonate film deposited at 2 W plasma power on a polytetrafluoroethylene (PTFE) substrate.

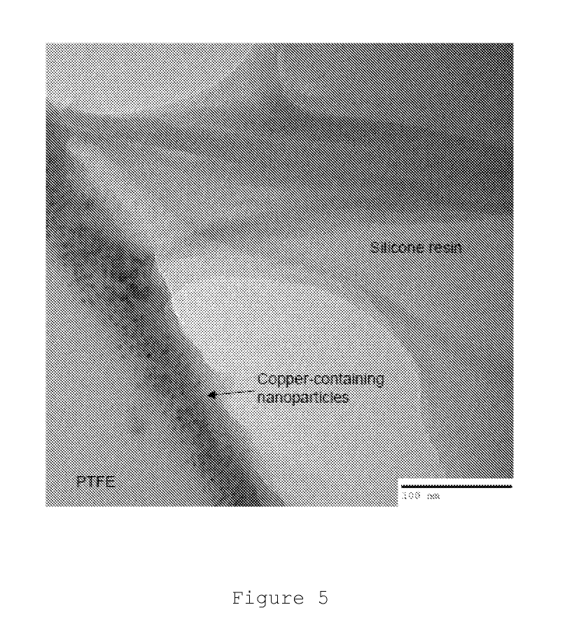

FIG. 5 shows a TEM image of copper(II) hexafluoroacetylacetonate film deposited at 5 W plasma power on a PTFE substrate.

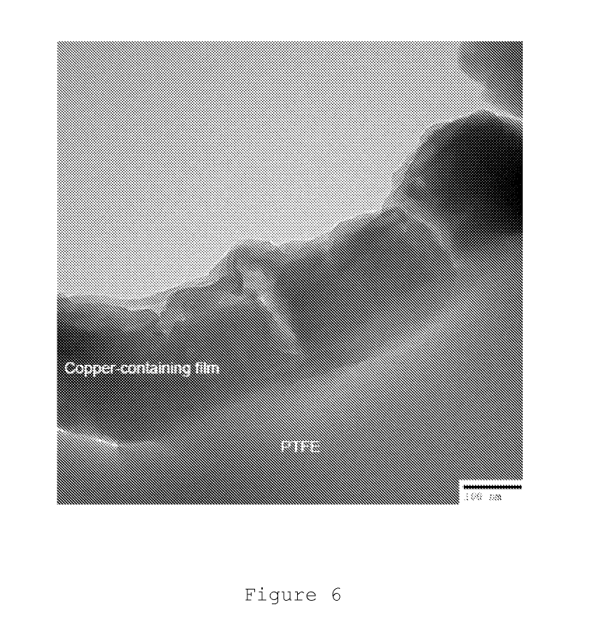

FIG. 6 shows a TEM image of copper(II) hexafluoroacetylacetonate film deposited at 10 W plasma power on a PTFE substrate.

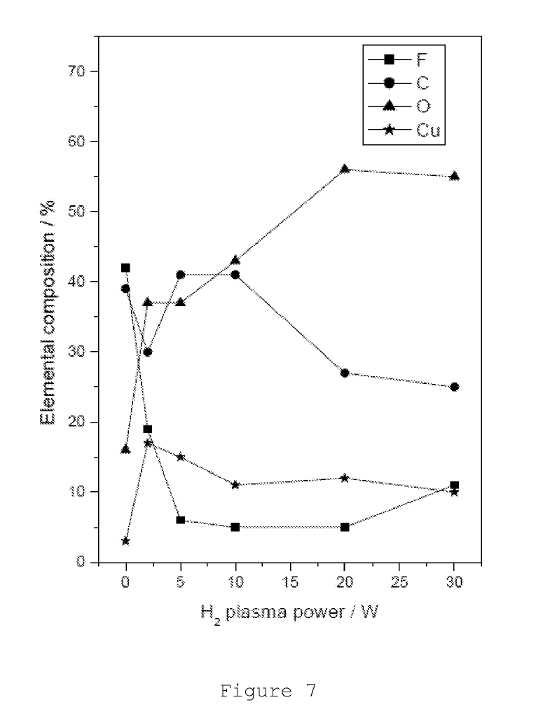

FIG. 7 shows the elemental composition determined by X-ray photoelectron spectroscopic analysis of plasma deposited copper(II) hexafluoroacetylacetonate films subjected to hydrogen plasmas with different powers.

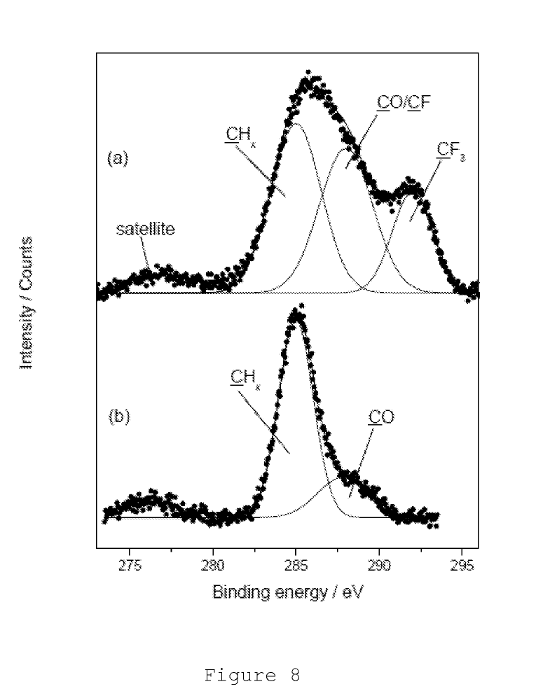

FIG. 8 shows C(1s) XPS spectra for plasma deposited copper(II) hexafluoroacetylacetonate (a) before, and (b) after 5 W hydrogen plasma treatment.

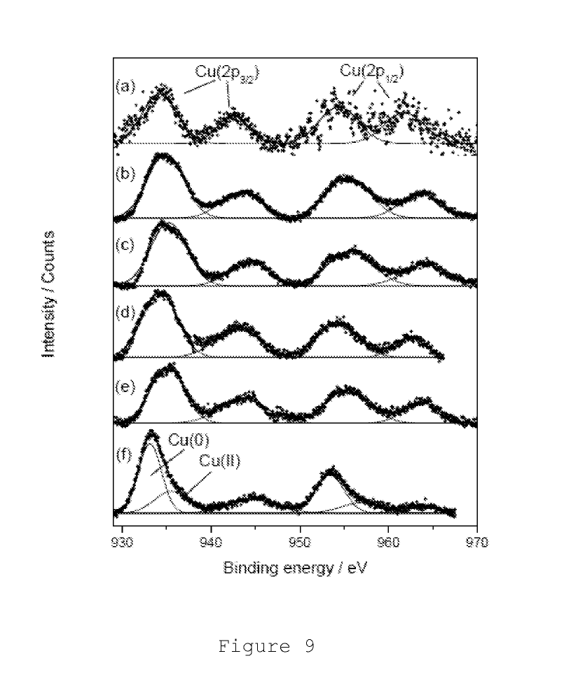

FIG. 9 shows Cu(2p) XPS spectra for plasma deposited copper(II) hexafluoroacetylacetonate films (a) before hydrogen plasma treatment, and after (b) 2 W, (c) 5 W, (d) 10 W, (e) 20 W and (f) 30 W hydrogen plasma treatment. Both the 2p_{3/2} and 2p_{1/2} peaks are shown with their shake up lines.

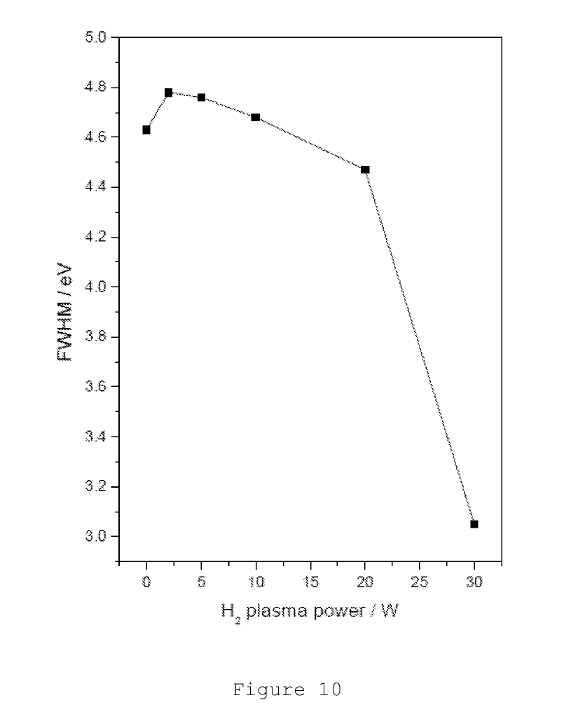

FIG. 10 shows Cu(2p_{3/2}) XPS peak full width half maxima (FWHM) as a function of hydrogen plasma treatment power for plasma deposited copper(II) hexafluoroacetylacetonate films before hydrogen plasma treatment and after 2 W, 5 W, 10 W, 20 W and 30 W hydrogen plasma treatment.

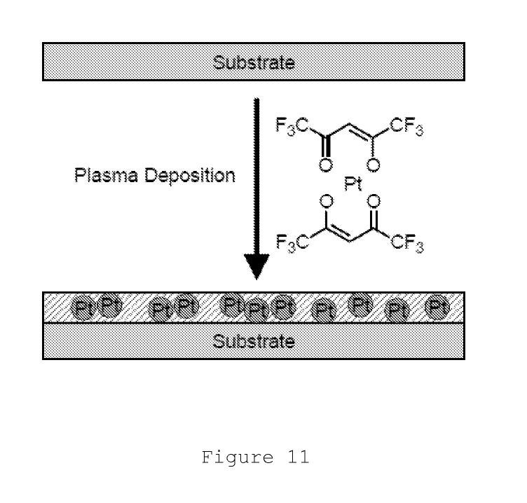

FIG. 11 shows a schematic representation of the plasmachemical deposition of platinum-polymer nanocomposite films.

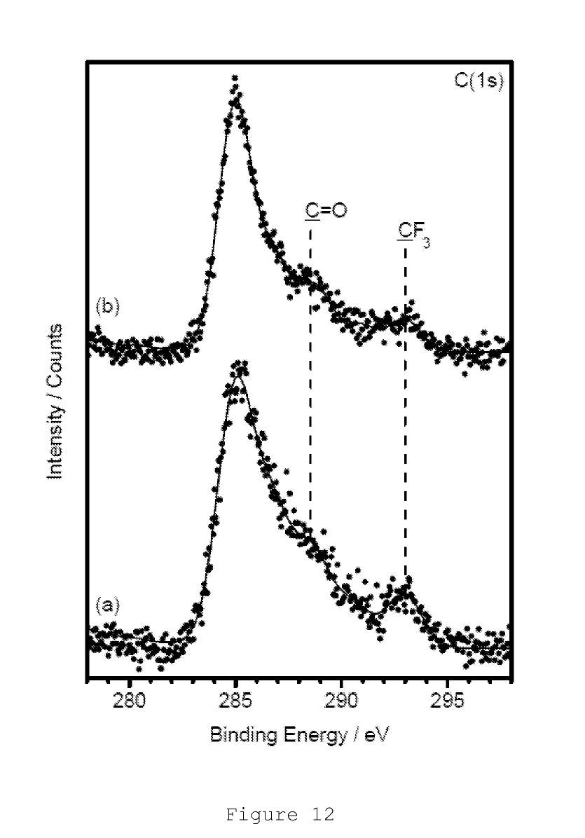

FIG. 12 shows C(1s)XPS spectra for plasma deposited platinum(II) hexafluoroacetylacetonate at plasma powers of: (a) 2 W and (b) 5 W.

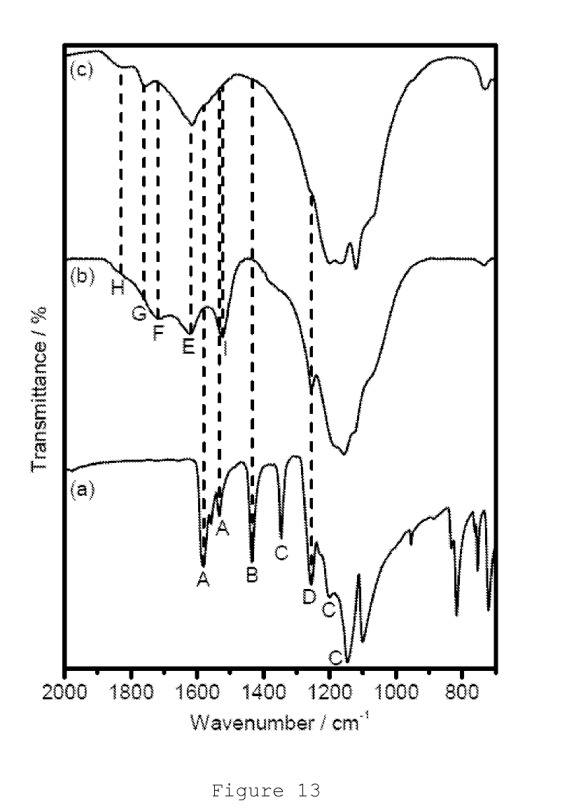

FIG. 13 shows FTIR spectra of (a): platinum(II) hexafluoroacetylacetonate precursor; and plasma deposited platinum(II) hexafluoroacetylacetonate at plasma powers of: (b) 2 W and (c) 5 W.

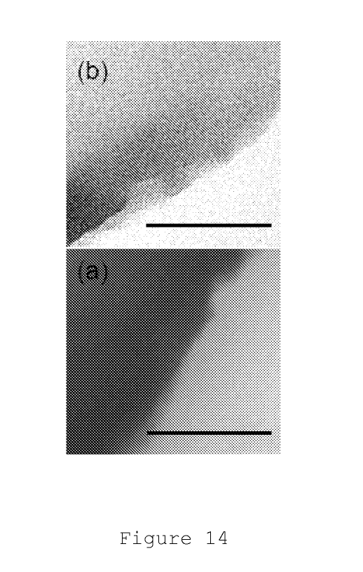

FIG. 14 shows transmission electron microscope images of plasma deposited platinum(II) hexafluoroacetylacetonate films: (a) 2 W and (b) 5 W. Scale bar=100 nm in both images.

### EXAMPLES

In these experiments, 2 W plasma power corresponds to a power density of 4.2 mW/cm³; 5 W plasma power corresponds to a power density of 10.4 mW/cm³; 10 W plasma power corresponds to a power density of 20.8 mW/cm³; 20 W plasma power corresponds to a power density of 41.7 mW/cm³; 30 W plasma power corresponds to a power density of 62.5 mW/cm³; and 40 W plasma power corresponds to a power density of 83.3 mW/cm³.

### Example 1

Herein we describe the use of plasma enhanced chemical vapour deposition (PEVCD) at temperatures below 100° C. to deposit nanocomposite films (films containing nanostructures): copper nanoparticles within a carbonaceous matrix. Post-deposition hydrogen plasma treatment is performed in order to increase the percentage metal content and reduce the copper(II) to copper(0). Analysis of these films is carried out by Fourier transform infrared (FTIR) spectroscopy, X-ray photoelectron spectroscopy (XPS) and impedance analysis.

Copper(II) hexafluoroacetylacetonate hydrate (Aldrich) was ground into a fine powder and loaded into a glass monomer tube. Plasma polymerization experiments were carried out in an electrodeless cylindrical glass reactor (volume of 480 cm³, base pressure of 3×10⁻² mbar, and with a leak rate better than 2×10⁻⁹ mol s⁻¹) surrounded by a copper coil (4 mm diameter, 10 turns), enclosed in a Faraday cage. The Faraday cage was insulated and had two neon heating bulbs attached to a thermostat. The chamber was pumped down using a 30 L min⁻¹ rotary pump attached to a liquid nitrogen cold trap; a Pirani gauge was used to monitor system pressure. The output impedance of a 13.56 MHz radio frequency (rf) power supply was matched to the partially ionized gas load. Before deposition the reactor had been scrubbed with cream cleaner, rinsed in acetone and dried in an oven. A continuous wave air plasma was run at 0.2 mbar pressure and 40 W power for 30 min to ensure the reactor was completely clean. Next, silicon (100) wafers (MEMC Materials Inc.) were put into the middle of the chamber on a glass support. With the thermostat set to 75° C., the precursor pressure corresponded to 0.08 mbar. A continuous wave plasma was used for plasma polymerization. Once deposition of the copper(II) hexafluoroacetylacetonate hydrate was complete, the rf generator was switched off and the precursor continued to be pumped through the system for a further 5 min as the system cooled down. Finally, the chamber was evacuated to base pressure to remove all the precursor vapour and then exposed to atmospheric pressure.

Plasmachemical film thickness measurements were carried out using an NKD-6000 spectrophotometer (Aquila Instruments Ltd.). Transmission and reflectance curves within the range 350-1000 nm wavelength were fitted to a Cauchy model for dielectric materials using a modified Levenberg-Marquardt method. The deposition rate of the copper(II) hexafluoroacetylacetonate film was up to 13 nm min⁻¹ depending on position of silicon substrate within the chamber.

Fourier transform infrared (FTIR) analyses of the plasmachemically deposited films were carried out using a Perkin-Elmer Spectrum One spectrometer (operating across the 4000-700 cm⁻¹ range) equipped with a liquid nitrogen cooled mercury cadmium telluride (MCT) detector. All spectra were averaged over 128 scans at a resolution of 4 cm⁻¹. Attenuated total reflection (ATR) measurements were taken using a single bounce diamond tip accessory (Graseby Specac Golden Gate). Reflection-absorption (RAIRS) measurements utilized a variable angle accessory (Graseby Specac) fitted with a KRS-5 polarizer (to remove the s-polarized component) and set at 66°.

A VG Escalab spectrometer equipped with an unmonochromatized Mg K X-ray source (1253.6 eV) and a concentric hemispherical analyzer were used for X-ray photoelectron spectroscopy (XPS) characterization of the plasmachemical films. Elemental compositions were calculated using sensitivity (multiplication) factors derived from chemical standards, C(1s):O(1s):F(1s):Cu(2p) 1.00:0.40:0.27:0.05.

Transmission electron microscopy (TEM) images were taken using a Phillips CM100 microscope. Polytetrafluoroethylene (PTFE) squares which had been coated with copper(II) hexafluoroacetylacetonate by plasmachemical deposition were embedded in an epoxy resin and then sectioned using a microtome. A copper grid supported the sections of the film and substrate.

Impedance measurements were carried out on membranes deposited on a glass substrate with two gold electrodes 5 mm long, separated by a distance of 1.5 mm. The impedance was measured using an HP 4192A LF impedance analyser across the frequency range from 10 Hz to 13 MHz. Films were fully hydrated at room temperature (20° C.) whilst the measurements were taken. Impedance plots took the form of two arcs, one at high frequency, one at lower frequencies and a 45° line at lower frequencies. The lower frequency arc was attributed to resistance due to charge transfer at the electrodes. The bulk resistance of the membrane was extracted from fitting the high frequency arc. The corresponding conductivity was calculated from the formula σ=1/RₛA, where σ is the membrane conductivity, Rₛ is the bulk membrane resistance, l is the length of the electrodes, and A is the cross-sectional area of the film. Charge transfer resistances were also found from fitting the low frequency impedance arcs in a similar fashion.

Hydrogen plasma reduction was carried out in the same chamber as the copper precursor plasmachemical deposition with hydrogen gas introduced into the chamber via a leak valve at 0.2 mbar. All hydrogen plasma reductions were carried out for 20 minutes, at room temperature (20° C.).

FTIR spectra for the plasma deposited copper(II) hexafluoroacetylacetonate and the precursor are presented in FIG. 2. For the precursor spectrum fingerprint region, distinct peaks can be seen between 1600 cm⁻¹ and 1800 cm⁻¹ which correspond to carbonyl stretching peaks. The very strongly absorbing peaks between 1120 cm⁻¹ and 1350 cm⁻¹ correspond to C—F stretches from the CF₃ groups. In the plasma deposited film, the fine structure of the precursor peaks has been lost as the individual peaks have broadened into two distinct bands corresponding to carbonyl peaks and C—F stretches (both CF₂ and CF₃). This broadening is attributed to a breakdown of structure under plasma deposition conditions. A plasma is a partially ionized gas with a high concentration of reactive ions and free radicals, therefore with a lack of an obvious point of polymerization (e.g. a vinyl or methacrylate group) structural retention is less than in conventional plasma polymerizations. However, despite a lack of structural retention, the trifluoromethyl and carbonyl functionalities are still present in the infrared spectrum. Of these carbonyl functionalities, some can be attributed to be carboxylic acid centres. XPS percentages of the plasma deposited film show good correlation to the atomic percentages calculated for the precursor (theoretical), thereby supporting structural retention, Table 1. This is due to the low power of the plasma (2 W) which promotes deposition of the precursor above ablation.

TABLE 1
Elemental Compositions of Plasma Deposited Copper(II)
Hexafluoroacetylacetonate Films (Plasma Power =
2 W): Experiment and Theoretical Values.

| | Elemental Composition/% | | | |
|---|---|---|---|---|
| Film | F | C | O | Cu |
| Plasma deposited copper(II) | 42 ± 1 | 39 ± 1 | 16 ± 1 | 3± |
| hexafluoroacetylacetonate | | | | |
| Theoretical | 44 | 37 | 15 | 4 |

The C(1s) XPS spectra for the copper(II) hexafluoroacetylacetonate films deposited with differing powers are shown in FIG. 3. It is clear that the continuous wave plasma does not deposit a film with highly distinct carbon environments. However, consistent with the infrared data, the CF₃ peak on the lower power deposition can be easily resolved (for the higher power, it is a shoulder).

FIGS. 4, 5 and 6 show the images obtained by transmission electron microscopy (TEM). As might be expected from the XPS data, a thin organic film is clearly visible in FIG. 4 (just over 200 nm thick). The low power film has withstood the epoxy resin embedding and microtome sectioning processes with no obvious damage. FIG. 6 shows a similar picture for the high power deposited copper(II) hexafluoroacetylacetonate with a thin organic film (just over 100 nm thick), but this time there are significant cracks and wrinkling within the film, which have occurred during the embedding and sectioning process. The thermal stress in the preparation procedure (along with the embedding and cutting procedures) causes the PTFE to deform somewhat, as seen by the curved substrate-film interface. The lower power copper(II) hexafluoroacetylacetonate film is able to withstand this procedure with no obvious damage, but the higher power film is mechanically unable to resist. This phenomenon can be directly related to the greater fragmentation of the copper(II) hexafluoroacetylacetonate that will be present in the higher power plasma. FIG. 5 shows the medium power plasma deposited copper(II) hexafluoroacetylacetonate film, but unlike the low and the high power films, there is a densely packed layer of copper containing nanoparticles embedded within the organic film (shown by the darker areas in the microscope image). All of the nanoparticles thus created within these nanocomposite films are significantly less than 10 nm in size.

TABLE 2
Ionic Conductivity Values Obtained from Impedance Analysis
of Plasmachemically Deposited Copper-containing Films.

| | Proton Conductivity/mS cm⁻¹ |
|---|---|
| Copper-containing film - | (from analysis of high |
| plasma deposition power | frequency impedance arc) |
| 2 W | 50 |
| 5 W | 34 |
| 10 W | 150 |

FIG. 7 shows the XPS elemental compositions of the copper(II) hexafluoroacetylacetonate films when exposed to varying powers of hydrogen plasma. There is a significant decrease in percentage fluorine at even low plasma powers, dropping from 42% to under 10% for 5 W hydrogen plasma treatment. This is expected, as the hydrogen reduction reaction should remove most of the hexafluoroacetylacetonate ligand. Any fluorine that is not part of a trifluoromethyl functionality should also form volatile products in the presence of hydrogen plasma (e.g. hydrofluoric acid). Additionally, the percentage carbon content decreases slightly as the hydrogen plasma power increases, whereas the percentage oxygen content increases significantly. Moreover, the percentage copper starts at 3%, peaks at 17% and then slowly decreases to ˜10% at higher hydrogen plasma powers. Therefore there is a significant increase in the percentage copper at the surface of the films due to hydrogen plasma treatment, which is attributed to the removal of volatile organics from the surface of the copper-containing film.

This is further correlated by the observed removal of the CF₃ peak in the carbon XPS spectrum with hydrogen plasma treatment, as can be seen in FIG. 8.

FIG. 9 shows the Cu(2p) XPS spectra for the plasma deposited copper(II) hexafluoroacetylacetonate film with varying power of hydrogen plasma treatment. In all the spectra there are shake up lines visible. These are due to the copper being copper(II), which is paramagnetic. Shake up lines are well known occurrences for first row transition metal compounds. These shake up lines are of similar sizes to the 2p_{3/2} and 2p_{1/2} peaks in all the films except the 30 W hydrogen plasma treated one, where they are significantly reduced in size. The 2p_{3/2} and 2p_{1/2} peaks for the 30 W hydrogen plasma treated film both have obvious tails, which indicates a mixture of copper(0) and copper(II) (there could also be some copper(I) which also shows shake up lines despite its diamagnetism). This is borne out by the full width half maxima of the Cu(2p_{3/2}) peaks shown in FIG. 10, where there is a significant reduction for the 30 W hydrogen plasma treated film. This is consistent with the formation of copper(0) at the surface.

### Example 2

In this investigation we describe the plasmachemical deposition of platinum-containing nanocomposite films at temperatures below 75° C., which concurrently display ionic and electrical conductivities, FIG. 11. Such multifunctional nanocomposite films are highly sought after for electrochemical device components, e.g. batteries and fuel cells. This is the first example of a single-step synthesis of such metal-containing nanocomposite materials.

Plasmachemical deposition was carried out in an electrodeless cylindrical glass reactor (volume of 480 cm³, base pressure of 3×10⁻³ mbar, and with a leak rate better than 2×10⁻⁹ mol s⁻¹) surrounded by a copper coil (4 mm diameter, 10 turns), all of which was contained within an oven set at 70° C. The chamber was pumped down using a 30 L min⁻¹ rotary pump attached to a liquid nitrogen cold trap, and a Pirani gauge was used to monitor system pressure. The output impedance of a 13.56 MHz radio frequency (rf) power supply was matched to the partially ionized gas load via an L-C circuit. Prior to each deposition, the reactor was scrubbed using detergent, rinsed in propan-2-ol, and dried in an oven. A continuous wave air plasma was then run at 0.2 mbar pressure and 40 W power for 30 min in order to remove any remaining trace contaminants from the chamber walls. Substrates used for coating were silicon (100) wafer pieces (Silicon Valley Microelectronics Inc.), polypropylene sheet (capacitor grade, Lawson Mardon Ltd.) with two evaporated gold electrodes (5 mm length and 1.5 mm separation) for conductivity testing, and poly(tetrafluoroethylene) (Goodfellow Cambridge Ltd.) for transmission electron microscopy. Platinum(II) hexafluoroacetylacetonate (+98%, Strem Chemicals Ltd.) precursor was loaded into a sealable glass tube and dried under vacuum. The reactor was then purged with precursor vapour for 5 min at a pressure of 0.1 mbar prior to electrical discharge ignition. The precursor was deposited using a continuous wave plasma at 70° C. Upon plasma extinction, the precursor vapour was allowed to continue to pass through the system for a further 3 min, in order to quench any remaining free radical sites within the films, and then the chamber was pumped back down to base pressure. Following deposition, the coated substrates were rinsed in deionized water for 16 h in order to test for film stability and adhesion.

Film thicknesses were measured using a spectrophotometer (nkd-6000, Aquila Instruments Ltd.). Transmittance-reflectance curves (350-1000 nm wavelength range) were acquired for each deposited layer and fitted to a Cauchy material model using a modified Levenberg-Marquardt algorithm (Lovering, D. NKD-6000 Technical Manual; Aquila Instruments: Cambridge, U.K., 1998). Typical film growth rates were 3-6 nm min⁻¹.

Elemental depth profiling measurements of platinum concentration were undertaken by the Rutherford backscattering technique (RBS) using a ⁴He⁺ ion beam (5SDH Pelletron Accelerator) in conjunction with a PIPS detector with 19 keV resolution.

Surface elemental compositions were determined by X-ray photoelectron spectroscopy (XPS) using a VG ESCALAB II electron spectrometer equipped with a non-monochromated Mg Kα X-ray source (1253.6 eV) and a concentric hemispherical analyser. Photoemitted electrons were collected at a take-off angle of 20° from the substrate normal, with electron detection in the constant analyser energy mode (CAE, pass energy=20 eV). Experimentally determined instrument sensitivity factors were taken as C(1s):O(1s):F(1s):Pt(4f) equals 1.00:0.34:0.26:0.05. All binding energies were referenced to the C(1s) hydrocarbon peak at 285.0 eV. A linear background was subtracted from core level spectra and then fitted using Gaussian peak shapes with a constant full-width-half-maximum (fwhm) (Friedman, R. M.; Hudis, J.; Perlman, M. L. Phys. Rev. Lett. 1972, 29, 692).

Infrared spectra were acquired using a FTIR spectrometer (Perkin-Elmer Spectrum One) fitted with a liquid nitrogen cooled MCT detector operating at 4 cm⁻¹ resolution across the 700-4000 cm⁻¹ range. The instrument included a variable angle surface reflection-absorption accessory (Specac Ltd.) set to a grazing angle of 66° for silicon wafer substrates and adjusted for p-polarization.

Transmission electron microscopy images were obtained using a Phillips CM100 microscope. Coated PTFE squares were embedded into an epoxy resin and then cross-sectioned using a cryogenic microtome. The cross-sections were then mounted onto copper grids prior to electron microscopy analysis.

Impedance measurements across the 10 Hz-13 MHz frequency range were carried out for coated polypropylene substrates at 20° C. using an LF impedance analyser (Hewlett-Packard, model 4192A) whilst submerged in ultra high purity water (resistivity greater than 18 MΩ cm, organic content less than 1 ppb, Sartorius Arium 611). The low frequency 45° line in the acquired impedance plots was assigned to the Warburg diffusion impedance, and a high frequency arc was fitted in order to extract the resistance of the deposited nanocomposite layer. 33 The formula σ=1/RₛA was used to calculate ionic conductivity, where σ is the membrane conductivity, Rₛ is the bulk membrane resistance, l is the distance between the electrodes, and A is the cross-sectional area of the film (Zawodzinski Jr., T. A.; Neeman, M.; Sillerud, L. O.; Gottesfeld, S. J. Phys. Chem. 1991, 95, 6040).

Electrical conductivity values were determined for the coated polypropylene substrates by measuring the variation in electrical current across the 0-200 V range (Keithley 2400 SourceMeter).

XPS analysis following the plasmachemical deposition of platinum-containing films indicated the absence of Si(2p) signal, which confirmed pin-hole free coverage of the underlying silicon substrate. The concentration of platinum measured by XPS is consistent with the Rutherford backscattering depth profiling studies (which confirmed constant level of metal content throughout the depth of the films), Table 3. Retention of the precursor trifluoromethyl (CF₃) groups within the deposited layers was evident by the distinct C(1s) XPS shoulder at 293.0 eV (Holmes, S. A.; Thomas, T. D. J. Am. Chem. Soc. 1975, 97, 2337), FIG. 12. This feature diminishes in intensity as plasma power is raised, which can be attributed to greater fragmentation and ablation of the precursor for more energetic plasma excitation. A broad, unresolvable shoulder at 288-289 eV is seen for the films, which is consistent with C═O groups being incorporated into the functional layers. This component was lower for the film deposited at 5 W plasma power, FIG. 12.

TABLE 3
Platinum content, ionic and electronic conductivity
of plasmachemically deposited platinum(II) hexafluoroacetylacetonate
films as a function of plasma power.

| | | | Ionic | Electrical |
|---|---|---|---|---|
| Plasma | Platinum content/atom % | | conductivity/ | conductivity/ |
| power/W | XPS | RBS | mS cm⁻¹ | 10⁻⁶ mS cm⁻¹ |
| 2 | 5.3 ± 0.3 | 4.3 ± 0.7 | 120 ± 10 | 12 ± 2 |
| 5 | 5.2 ± 0.3 | 4.3 ± 0.7 | 95 ± 8 | 31 ± 1 |

Infrared spectroscopy gave further evidence for structural retention within the nanocomposite films, FIG. 13. For the platinum(II) hexafluoroacetylacetonate precursor, the following assignments can be made: a mixture of C═C and C═O stretches (1581 cm⁻¹ and 1532 cm⁻¹, denoted A), chelate C—H deformation (1434 cm⁻¹, denoted B), CF₃ stretches (1346 cm⁻¹, 1196 cm⁻¹ and 1146 cm⁻¹, denoted C), and C═C chelate stretch (1255 cm⁻¹, denoted D). For the plasmachemical deposited platinum(II) hexafluoroacetylacetonate layers, the carbonyl C═O stretches split into several regions including the original beta-diketonate stretches (A), beta-diketone stretch (1620 cm⁻¹, denoted E), carboxylic acid dimer stretch (1705 cm⁻¹, denoted F), carboxylic anhydride antisymmetric stretch (1754 cm⁻¹, denoted G), and carboxylic anhydride symmetric stretch (1826 cm⁻¹, denoted H). For all the plasma-deposited films the C—H deformation (B) is shifted to 1524 cm⁻¹ (denoted I), which is consistent with a new environment for the chelate unit (i.e. unbound precursor is absent). The plasma-deposited films also show broad stretches over the 1100-1400 cm⁻¹ region, which is consistent with CFₓ stretches, and the retention of the shoulder at 1255 cm⁻¹ attributable to C═C chelate stretching (D). Whilst the plasma-deposited films appear similar in nature, there are some differences including more intense chelate C—H deformation and C═C stretch (D and I) peaks for the case of 2 W input plasma power (corresponding to less fragmentation at lower energies); also there is a significant loss of the carboxylic acid dimer peak (F) at 5 W plasma deposition.

Transmission electron microscopy shows a homogeneous (highly dispersed metal) film for plasmachemical deposition at 2 W, FIG. 14. However, for the case of the layer deposited at 5 W plasma power, there are distinct metal nanoparticles visible within the films, which are all significantly less than 5 nm in size. The organic host matrix is clearly discernible surrounding the nanoparticles.

Ionic conductivity measurements of the plasmachemical deposited nanocomposite films whilst immersed in ultrahigh purity water showed high values exceeding 100 mS cm⁻¹, Table 3. This can be attributed to the presence of fluorinated, carboxylic acid moieties within the films, as evidenced by infrared spectroscopy. Such strong acidic groups can be expected to give rise to a high degree of acid dissociation under fully hydrated conditions, which in turn manifests in proton conductivity. Ionic conductivity values were lower for the deposited 5 W films, which correlates to the weaker acidic infrared absorbances, FIG. 13.

The plasmachemically deposited, platinum-polymer films also exhibit significant electronic conduction, Table 3. This conductivity is greater by a factor greater than 2 in the case of the 5 W plasma-deposited film (3.1×10⁻⁵ mS cm⁻¹), and is seen to coincide with the decrease in acid-containing groups (as shown by FTIR). Given the small particle sizes within the 5 W plasma-deposited films, the observed atomic percentage of platinum within the films is high enough (5 atom %) for percolation to take place, whereby conducting particles within an insulating medium are close enough for electron tunnelling and therefore conduction to take place.

In contrast to earlier studies, where plasmachemically deposited nanocomposite layers were unstable in water, the present films did not display any deterioration in performance (Duque, L.; Forch, R. Plasma Processes Polym. 2011, 8, 444).

Mixed ionic-electronic conductors are desirable for use as electrode materials in, for example, solid state batteries, fuel cells, electrochemical reactors, and light-emitting electrochemical cells. They can comprise inorganic crystalline materials, conjugated polymers, or heterogeneous polymeric systems and copolymers (i.e. mixtures of ion-conducting and conjugated, electron-conducting parts). All these systems require separate steps for manufacture and incorporation into an electrochemical device (usually via solution casting or spin coating in the case of polymeric systems). In this example the use of one-step plasmachemical deposition of a single precursor, platinum(II) hexafluoroacetylacetonate, gives rise to electron- and ion-conducting nanocomposite films. The conformal nature of the deposited films means that the manufacturing step can be combined with coating parts of electrochemical devices (e.g. carbon cloth).

By careful tuning of the plasma power, platinum-containing nanoparticles are formed within the organic matrix. The formation of nano-sized platinum-containing structures within the film requires the applied plasma power surpassing an activation barrier, which is the reason for the homogeneity of the film deposited at 2 W plasma power. The activation barrier for the fragmentation of the organic chelate into various carbonyl-containing moieties is lower as evidenced by the presence of carboxylic acid and anhydride infrared peaks in the films deposited at both powers. There was no variation in the properties of the deposited films regardless of their position within the reactor; this phenomenon is due to the low powers used in this example—at higher powers metal-content gradients have been observed. The organic matrix, within which the platinum-containing nanoparticles are located, also shows ionic conductivity along with good stability under hydrated conditions, whereas nanocomposite films previously manufactured via plasmachemical deposition have either produced unstable organic matrices, or required high plasma powers in order to induce sputtering from an inorganic target.

Metal hexafluoroacetylacetonates have in the past been used to deposit inorganic-only films via chemical vapour deposition methods especially for use in microelectronic devices. With low temperature (70° C.) plasmachemical deposition, however, a functional, organic layer is retained. The trifluoromethyl groups in the platinum(II) hexafluoroacetylacetonate serve a dual purpose: firstly they give the precursor a higher vapour pressure (thus enabling lower temperature deposition), and secondly, when the precursor breaks up within the plasma (forming carboxylic acid groups), fluorination provides an electron-withdrawing effect, which is known to result in stronger acid groups (and therefore higher proton conductivity when immersed in water). This is the first time that plasmachemical deposition of a single precursor under mild conditions has been used to deposit a robust, metal-containing, nanocomposite film, exhibiting both electronic and ionic conductivity.

This plasmachemical process uses low temperatures compared to many chemical vapour deposition methods, and low plasma powers, which therefore makes it suitable for coating a wide range of substrates, especially those which are thermally sensitive. Added advantages include conformal deposition of two- and three-dimensional substrates, along with no requirement for solvents, drying, or postdeposition modification. As such this plasma-deposition technique can be used in conjunction with high-throughput coating techniques, such as roll-to-roll processing. The platinum-containing nanocomposite films are catalytically active, and the ionic and electronic conductivity of these films mean a single-step plasmachemical coating of electrochemical device components (e.g. within fuel cells or batteries) could be envisaged.

Low power, low temperature plasmachemical deposition has been utilized to manufacture platinum-containing nanocomposite films. Careful tailoring of the plasma power produces platinum-containing nanoparticles within a robust, organic matrix. The resultant films show ionic conductivity along with electronic conductivity. This plasmachemical deposition process offers a single-step, low power, low temperature method for conformally coating substrates with platinum-containing nanocomposite layers, resulting in ease of manufacture and low cost.

1. A method for forming a conducting nanocomposite layer on a substrate, the method comprising depositing a precursor on the substrate by plasma deposition, wherein the precursor comprises
(i) a metal or metalloid centre, and
(ii) one or more organic ligands,
and wherein the conditions of the plasma deposition are tailored such that an organic matrix is retained in the resulting conducting nanocomposite layer.

2. The method of claim 1, wherein plasma deposition is performed at a temperature of up to 200° C.

3. The method of claim 1, wherein the plasma deposition occurs at a power density of 1 mW/cm³ to 100 mW/cm³.

4. The method of claim 1, wherein the plasma deposition is a continuous wave plasma deposition process.

5. The method of claim 1, wherein the conducting nanocomposite layer is ion-conducting and/or electron-conducting.

6. The method of claim 1, wherein the metal or metalloid centre gives rise to electron-conducting or semiconducting species in the resulting conducting nanocomposite layer.

7. The method of claim 1, wherein the one or more organic ligands give rise to ion-conductivity, proton-conductivity, electron-conductivity or semiconductivity, or any combination thereof, in the resulting conducting nanocomposite layer.

8. The method of claim 1, wherein the metal or metalloid centre comprises platinum, palladium, ruthenium, rhodium, gold, silver, copper, nickel, iron, cobalt, molybdenum, titanium, zinc, tin, or any combination thereof.

9. The method of claim 8, wherein the metal or metalloid centre comprises platinum or copper.

10. The method of claim 1, wherein the one or more organic ligands comprise ligands selected from at least partially substituted or unsubstituted acetylacetonate ligands, isopropoxide ligands, acetate ligands, and any combination thereof.

11. The method of claim 10, wherein the one or more organic ligands comprise hexafluoroacetylacetonate.

12. The method of claim 10, wherein the precursor comprises a compound selected from platinum(II) hexafluoroacetylacetonate, copper(II) hexafluoroacetylacetonate, zinc acetylacetonate, titanium isopropoxide, tin acetate, and any combination thereof.

13. A conducting nanocomposite layer which is obtainable by the method of claim 1.

14. An electrode comprising a substrate and a conducting nanocomposite layer according to claim 13 on said substrate.

15. An apparatus comprising a substrate and a conducting nanocomposite layer according to claim 13 on said substrate.

16. The method of claim 1, wherein the plasma deposition is a pulsed plasma deposition process.

17. The method of claim 16, wherein the metal or metalloid centre comprises platinum or copper.

18. The method of claim 16, wherein the one or more organic ligands comprise hexafluoroacetylacetonate.

19. The method of claim 17, wherein the one or more organic ligands comprise hexafluoroacetylacetonate.

20. The method of claim 19, wherein the precursor comprises a compound selected from platinum(II) hexafluoroacetylacetonate and copper(II) hexafluoroacetylacetonate.
